(19) United States
(12) Patent Application Publication
(10) Pub. No.: US 2023/0200196 A1
(43) Pub. Date: Jun. 22, 2023

(54) DEPOSITION DEVICE AND DEPOSITION METHOD

(71) Applicant: Samsung Display Co., LTD., Yongin-si (KR)

(72) Inventors: Sijin SUNG, Hwaseong-si (KR); Ill Soo PARK, Asan-si (KR)

(73) Assignee: Samsung Display Co., LTD., Yongin-si (KR)

(21) Appl. No.: 17/745,365

(22) Filed: May 16, 2022

(30) Foreign Application Priority Data
Dec. 16, 2021 (KR) 10-2021-0180605

(51) Int. Cl. H01L 51/56; C23C 14/24; H01L 27/32; H01L 51/00

(52) U.S. Cl. CPC H01L 51/56; C23C 14/24; H01L 27/3244; H01L 51/001; H01L 51/0011

(57) ABSTRACT

A deposition device according to an embodiment includes a first deposition source, a second deposition source, and a third deposition source arranged sequentially in a first direction, a first angle limitation plate disposed outside of the first deposition source, a second angle limitation plate disposed between the first deposition source and the second deposition source, a third angle limitation plate disposed between the second deposition source and the third deposition source, and a fourth angle limitation plate disposed outside the third deposition source. A deposition material of the first deposition source and a deposition material of the third deposition source include a same dopant material. A deposition material of the second deposition source includes a host material.

### CROSS-REFERENCE TO RELATED APPLICATION(S)

This application claims priority to and the benefit of Korean Patent Application No. 10-2021-0180605 under 35 U.S.C. § 119, filed in the Korean Intellectual Property Office on Dec. 16, 2021, the entire contents of which are incorporated herein by reference.

### BACKGROUND

### 1. Technical Field

The disclosure relates to a deposition device and a deposition method.

### 2. Description of the Related Art

An emissive display device includes a light-emitting element including an anode, an emission layer, and a cathode. The light-emitting element may be a light emitting diode (LED) in which holes and electrons are respectively injected from the anode and the cathode to form excitons, and the excitons are transited to a ground state and emit light.

In the manufacturing process of the emissive display device, the emission layer may be formed by a thin film deposition process using a deposition device. The deposition device includes a deposition source including a deposition material. When the deposition source is heated, the deposition material in the deposition source is vaporized, and the vaporized deposition material is sprayed through a nozzle. The sprayed deposition material is deposited on a substrate to form a thin film.

If the emission layer contains multiple materials, more than one deposition source can be used in a single chamber.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments may improve the lifetime of the light-emitting element by improving doping uniformity in a film thickness direction of the emission layer of the display device. Embodiments may reduce thermal degradation of a deposition material.

A deposition device according to an embodiment may include a first deposition source, a second deposition source, and a third deposition source arranged sequentially in a first direction, a first angle limitation plate disposed outside of the first deposition source, a second angle limitation plate disposed between the first deposition source and the second deposition source, a third angle limitation plate disposed between the second deposition source and the third deposition source, and a fourth angle limitation plate disposed outside the third deposition source. A deposition material of the first deposition source and a deposition material of the third deposition source may include a same dopant material. A deposition material of the second deposition source may include a host material.

The host material from the second deposition source may include a host material of a green emission layer. The dopant material from the first deposition source and the dopant material from the third deposition source may include a dopant material of the green emission layer.

The first deposition source, the second deposition source, and the third deposition source may move in the first direction and spray the deposition material.

The first deposition source, the second deposition source, and the third deposition source may extend in a second direction substantially perpendicular to the first direction.

Each of the first deposition source, the second deposition source, and the third deposition source may include a spray hole. The spray hole may include spray nozzles arranged in the second direction, or may include a linear nozzle that extends in the second direction.

An incident angle from the first deposition source to a substrate of the deposition material limited by the first angle limitation plate may be a first incident angle. An incident angle from the first deposition source to the substrate of the deposition material limited by the second angle limitation plate may be a second incident angle. An incident angle from the second deposition source to the substrate of the deposition material limited by the second angle limitation plate may be a third incident angle. An incident angle from the second deposition source to the substrate of the deposition material limited by the third angle limitation plate may be a fourth incident angle. An incident angle from the third deposition source to the substrate of the deposition material limited by the third angle limitation plate may be a fifth incident angle. An incident angle from the third deposition source to the substrate of the deposition material limited by the fourth angle limitation plate may be a sixth incident angle. Each of the first incident angle and the sixth incident angle may be larger than either of the third incident angle or the fourth incident angle.

Each of the third incident angle and the fourth incident angle may be larger than either of the second incident angle or the fifth incident angle.

Each of a height of the first angle limitation plate and a height of the fourth angle limitation plate may be higher than either of a height of the second angle limitation plate or a height of the third angle limitation plate.

The first incident angle and the sixth incident angle may be substantially equal to each other. The third incident angle and the fourth incident angle may be substantially equal to each other. The second incident angle and the fifth incident angle may be substantially equal to each other.

A height of the first angle limitation plate and a height of the fourth angle limitation plate may be substantially equal to each other. A height of the second angle limitation plate and a height of the third angle limitation plate may be substantially equal to each other.

The first incident angle and the sixth incident angle may be in a range of about 72 degrees to about 82 degrees. The third incident angle and the fourth incident angle may be in a range of about 55 degrees to about 65 degrees. The second incident angle and the fifth incident angle may be in a range of about 50 degrees to about 60 degrees.

A region where the dopant material from the first deposition source is deposited on the substrate and a region where the dopant material from the third deposition source is deposited on the substrate may partially overlap in a plan view. A region where the host material from the second deposition source is deposited on the substrate may overlap substantially all of the region where the dopant material from the first deposition source is deposited on the substrate, in a plan view. The region where the host material from the second deposition source is deposited on the substrate overlaps substantially all of the region where dopant material from the third deposition source is deposited on the substrate, in a plan view.

A deposition device according to an embodiment may include a first deposition source, a second deposition source, and a third deposition source arranged sequentially in a direction. A deposition material from the first deposition source and a deposition material from the third deposition source may include a same dopant material. A deposition material of the second deposition source may include a host material. A region where the dopant material from the first deposition source is deposited on a substrate, and a region where the dopant material from the third deposition source is deposited on the substrate may partially overlap in a plan view. A region where the host material from the second deposition source is deposited on the substrate may overlap substantially all of the region where the dopant material from the first deposition source is deposited on the substrate, in a plan view. The region where the host material from the second deposition source is deposited on the substrate may overlap substantially all of the region where the dopant material from the third deposition source is deposited on the substrate, in a plan view.

The host material from the second deposition source may include of a host material of a green emission layer, and the dopant material from the first deposition source and the dopant material from the third deposition source may include a dopant material of the green emission layer.

The first deposition source, the second deposition source, and the third deposition source may move in the direction and spray the deposition material.

The deposition device may further include a first angle limitation plate disposed outside of the first deposition source, a second angle limitation plate disposed between the first deposition source and the second deposition source, a third angle limitation plate disposed between the second deposition source and the third deposition source, and a fourth angle limitation plate disposed outside of the third deposition source.

Each of a height of the first angle limitation plate and a height of the fourth angle limitation plate may be higher than either of a height of the second angle limitation plate or a height of the third angle limitation plate. The height of the first angle limitation plate and the height of the fourth angle limitation plate may be substantially equal to each other. The height of the second angle limitation plate and the height of the third angle limitation plate may be substantially equal to each other.

A deposition method according to an embodiment may include moving the first deposition source, the second deposition source, and the third deposition source in a direction with respect to a substrate, depositing a dopant material from the first deposition source and from the third deposition source on the substrate, and depositing a host material from the second deposition source on the substrate. A deposition device may include the first deposition source, the second deposition source, the third deposition source and angle limitation plates. The first deposition source, the second deposition source, and the third deposition source may be sequentially arranged in the direction.

The host material from the second deposition source may include a host material of a green emission layer. The dopant material from the first deposition source and from the third deposition source may include a dopant material of the green emission layer.

The angle limitation plates may include a first angle limitation plate, a second angle limitation plate, a third angle limitation plate, and a fourth angle limitation plate. The first angle limitation plate, the second angle limitation plate, the third angle limitation plate, and the fourth angle limitation plate may be arranged sequentially in the direction. An incident angle from the first deposition source to the substrate of the deposition material limited by the first angle limitation plate may be a first incident angle. An incident angle from the first deposition source to the substrate of the deposition material limited by the second angle limitation plate may be a second incident angle. An incident angle from the second deposition source to the substrate of the deposition material limited by the second angle limitation plate may be a third incident angle. An incident angle from the second deposition source to the substrate of the deposition material limited by the third angle limitation plate may be a fourth incident angle. An incident angle from the third deposition source to the substrate of the deposition material limited by the third angle limitation plate may be a fifth incident angle. An incident angle from the third deposition source to the substrate of the deposition material limited by the fourth angle limitation plate may be a sixth incident angle. The first incident angle and the sixth incident angle may be in a range of about 72 degrees to about 82 degrees. The third incident angle and the fourth incident angle may be in a range of about 55 degrees to about 65 degrees. The second incident angle and the fifth incident angle may be in a range of about 50 degrees to about 60 degrees.

According to embodiments, the lifetime of the light-emitting element may be improved by improving doping uniformity in the layer thickness direction of the emission layer of the display device. It may be possible to reduce the thermal degradation of the deposition material.

### BRIEF DESCRIPTION OF THE DRAWINGS

The above and other aspects and features of the disclosure will become more apparent by describing in detail embodiments thereof with reference to the attached drawings, in which:

FIG. 1 is a schematic view of a deposition device and a deposition method according to an embodiment,

FIG. 2 is a schematic view of a deposition device and a deposition method according to a comparative example,

FIG. 3 is a graph showing a ratio of a dopant and a host depending on a thickness of a layer deposited according to a deposition method according to a comparative example,

FIG. 4 is a graph showing a ratio of a dopant and a host depending on a thickness of a layer deposited according to a deposition method according to an embodiment,

FIG. 5 is a graph comparing the luminance change over time of a pixel of a color formed by a deposition method using a deposition device according to an embodiment and a comparative example,

FIG. 6 is a table showing a lifetime increasing rate of a light-emitting element of a color formed by a deposition method using a deposition device according to an embodiment and a comparative example,

FIG. 7 is a graph showing a luminance change over time of a pixel of all colors formed by a deposition method using a deposition device according to an embodiment and a comparative example,

FIG. 8 is a table showing a lifetime increasing rate of a light-emitting element of all colors formed by a deposition method using a deposition device according to an embodiment and a comparative example,

FIG. 9 is a schematic plan view of a display device according to an embodiment, and

FIG. 10 is a schematic cross-sectional view of a display device according to an embodiment.

### DETAILED DESCRIPTION OF THE EMBODIMENTS

The embodiments will be described more fully hereinafter with reference to the accompanying drawings, in which embodiments are shown. As those skilled in the art would realize, the described embodiments may be modified in various different ways, all without departing from the spirit or scope of the disclosure.

Descriptions of parts not related to the embodiments are omitted, and like reference numerals designate like elements throughout the specification.

Further, since sizes and thicknesses of constituent members shown in the accompanying drawings are arbitrarily given for better understanding and ease of description, the embodiments are not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Unless explicitly described to the contrary, the word “comprise,” and variations such as “comprises” or “comprising,” will be understood to imply the inclusion of stated elements but not the exclusion of any other elements.

Further, in the specification, the phrase “in a plan view” means viewing the object portion from the top, and the phrase “on a cross-section” means viewing a cross-section of which the object portion is vertically cut from the side.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

“About,” “substantially,” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

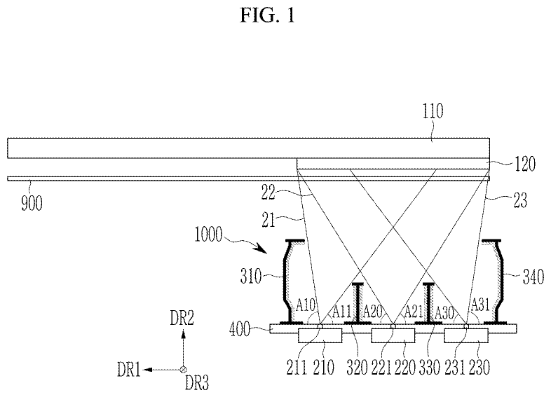

A deposition device and a deposition method according to an embodiment are described with reference to FIG. 1.

FIG. 1 is a view showing a deposition device and a deposition method according to an embodiment.

A deposition device 1000 according to an embodiment is a deposition device for depositing an emission layer 120 of a light-emitting element on a substrate 110 in a chamber, and includes a first deposition source 210, a second deposition source 220, a third deposition source 230, and angle limitation plates 310, 320, 330, and 340.

The first deposition source 210, the second deposition source 220, and the third deposition source 230 may be disposed on a base 400, and in FIG. 1, may be sequentially arranged in approximately the first direction DR1. The positions of the first deposition source 210 and the third deposition source 230 may be interchanged.

The deposition materials of the first deposition source 210, the second deposition source 220, and the third deposition source 230 may be vaporized by heat and sprayed toward the substrate 110. Each of the first deposition source 210, the second deposition source 220, and the third deposition source 230 may include spray holes 211, 221, and 231 for spraying vaporized deposition materials.

Each of the first deposition source 210, the second deposition source 220, and the third deposition source 230 may be a linear deposition source that extends lengthwise in the third direction DR3 in FIG. 1 to scan the substrate 110 in the first direction DR1 and deposit the deposition material. The third direction DR3 may be substantially perpendicular to the first direction DR1.

Each of the spray holes 211, 221, and 231 of the first deposition source 210, the second deposition source 220, and the third deposition source 230 may include spray nozzles arranged in the third direction DR3 or a linear nozzle that extends in the third direction DR3. Therefore, it is possible to reduce the deviation of the thickness of the layer such as the emission layer 120 deposited on the substrate 110, use a deposition source with a large capacity, and perform an efficient deposition process on the substrate 110 in a large area.

The first deposition source 210, the second deposition source 220, and the third deposition source 230 fixed to the base 400 move in the first direction DR1 in FIG. 1 and deposit an emission layer material on the substrate 110 to form emission layers 120. Multiple layers such as a conductive layer and an insulating layer that are already formed may be disposed between the emission layer 120 and the substrate 110.

A mask 900 including openings may be disposed between the substrate 110 and the deposition device 1000 to form an emission layer 120 only in selected regions on the substrate 110. The mask 900 may include a fine metal mask (FMM).

According to an embodiment, the emission layer material may be an organic light emitting material.

When pixels, the light emitting units of the display device according to an embodiment, emit light in multiple colors, the first deposition source 210, the second deposition source 220, and the third deposition source 230 included in the deposition device 1000 according to an embodiment may include a material of an emission layer of a pixel having the highest luminance among a plurality of colors as a deposition material. For example, when a plurality of pixels included in the display device according to an embodiment include a red pixel, a green pixel, and a blue pixel, the first deposition source 210, the second deposition source 220, and the third deposition source 230 included in the deposition device 1000 according to the embodiment may include a material of a green emission layer of a green pixel.

Among the first deposition source 210, the second deposition source 220, and the third deposition source 230, the deposition materials of the first deposition source 210 and the third deposition source 230 disposed at both edges include the same dopant material as the emission layer, and the deposition material of the second deposition source 220 disposed at the center includes the host material of the emission layer. The emission layer may be a green emission layer.

The angle limitation plates 310, 320, 330, and 340 may limit the incident angle that the deposition material sprayed from each of the spray holes 211, 221, and 231 of the first deposition source 210, the second deposition source 220, and the third deposition source 230 is incident on the substrate 110.

Here, the incident angle, since a range in which the deposition material sprayed from each of the spray holes 211, 221, and 231 passes toward the substrate 110 by the angle limitation plates 310, 320, 330, and 340 disposed on either side of each of the spray holes 211 221, and 231 is limited means an angle formed by the edges of profiles 21, 22, and 23 of the deposition material incident toward the substrate 110 with the top surface of the base 400. The incident angle is also referred to as a deposition angle. The edges of the profiles 21, 22, and 23 of the deposition materials may be in a form extending to the third direction DR3 in FIG. 1.

Each of the angle limitation plates 310, 320, 330, and 340 may extend in the third direction DR3 in FIG. 1 to be fitted to each of the linear first deposition source 210, second deposition source 220, and third deposition source 230.

The angle limitation plates 310, 320, 330, and 340 include the first angle limitation plate 310 disposed outside the first deposition source 210, the second angle limitation plate 320 disposed between the first deposition source 210 and the second deposition source 220, the third angle limitation plate 330 disposed between the second deposition source 220 and the third deposition source 230, and the fourth angle limitation plate 340 disposed outside the third deposition source 230.

Therefore, the first angle limitation plate 310 and the second angle limitation plate 320 are disposed on both sides of the first deposition source 210, the second angle limitation plate 320 and the third angle limitation plate 330 are disposed on both sides of the second deposition source 220, and the third angle limitation plate 330 and the fourth angle limitation plate 340 are disposed on both sides of the third deposition source 230.

The first angle limitation plate 310 may limit the incident angle so that the left edge of the profile 21 of the deposition material injected from the first deposition source 210 is incident on the substrate 110 at the first incident angle A10, and the second angle limitation plate 320 may limit the incident angle so that the right edge of the profile 21 of the deposition material injected from the first deposition source 210 is incident on the substrate 110 at a second incident angle A11.

The second angle limitation plate 320 may limit the incident angle so that the left edge of the profile of the deposition material 22 injected from the second deposition source 220 is incident on the substrate 110 at a third incident angle A20, and the third angle limitation plate 330 may limit the incident angle such that the right edge of the profile of the deposition material 22 injected from the second deposition source 220 is incident on the substrate 110 at a fourth incident angle A21.

The third angle limitation plate 330 may limit the incident angle so that the left edge of the profile of the deposition material 23 injected from the third deposition source 230 is incident on the substrate 110 at a fifth incident angle A30, and the fourth angle limitation plate 340 may limit the incident angle such that the right edge of the profile of the deposition material 23 injected from the third deposition source 230 is incident on the substrate 110 at a sixth incident angle A31.

The first incident angle A10 and the sixth incident angle A31 are greater than the third incident angle A20 and the fourth incident angle A21, and the third incident angle A20 and the fourth incident angle A21 are greater than the second incident angle A11 and the fifth incident angle A30. Among the first to sixth incident angles A10, A11, A20, A21, A30, and A31, the first incident angle A10 and the sixth incident angle A31 may be the largest, and the second incident angle A11 and the fifth incident angle A30 may be the smallest.

The height in the second direction DR2 of the first angle limitation plate 310 and the fourth angle limitation plate 340 may be higher than the height in the second direction DR2 of the second angle limitation plate 320 and the third angle limitation plate 330. The second direction DR2 may be substantially perpendicular to the first direction DR1 and the third direction DR3.

The first incident angle A10 may be equal to the sixth incident angle A31, the third incident angle A20 may be equal to the fourth incident angle A21, and the second incident angle A11 may be equal to the fifth incident angle A30.

The first angle limitation plate 310 and the fourth angle limitation plate 340 may have the same height in the second direction DR2, and the second angle limitation plate 320 and the third angle limitation plate 330 may have the same height in the second direction DR2.

The first incident angle A10 and the sixth incident angle A31 may be in a range of about 72 degrees to about 82 degrees, the third incident angle A20 and the fourth incident angle A21 may be in a range of about 55 to about 65 degrees, and the second incident angle A11 and the fifth incident angle A30 may be in a range of about 50 degrees to about 60 degrees. For example, the first incident angle A10 and the sixth incident angle A31 may be approximately 77 degrees, the third incident angle A20 and the fourth incident angle A21 may be approximately 60 degrees, and the second incident angle A11 and the fifth incident angle A30 may be approximately 55 degrees.

By depositing on the substrate 110 by using the deposition device 1000 as described above, the dopant material of the first and third deposition sources 210 and 230 and the host material of the second deposition source 220 may be co-deposited on the substrate 110.

Referring to FIG. 1, the region where the dopant material from the first deposition source 210 is deposited on the substrate 110 and the region where the dopant material from the third deposition source 230 is deposited on the substrate 110 may partially overlap in a plan view of the substrate 110. The region where the host material from the second deposition source 220 is deposited on the substrate 110 may overlap the region where the dopant materials from the first and third deposition sources 210 and 230 are deposited on the substrate 110 in a plan view. However, the disclosure is not limited thereto.

The deposition device 1000 according to an embodiment may perform the deposition while scanning once in the first direction DR1 with respect to the substrate 110, or may perform the deposition while reciprocating (e.g., moving back and forth in the first direction DR1) one or more times.

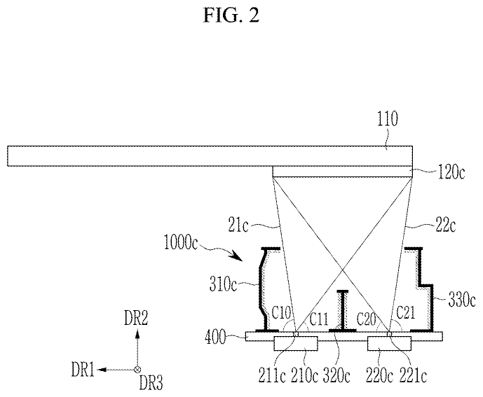

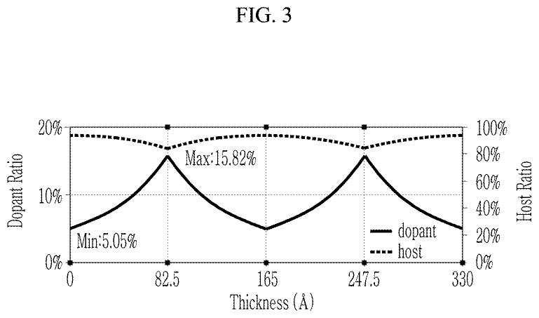

A comparative example that may be compared with the embodiment shown in FIG. 1 is described in FIG. 2 and FIG. 3.

FIG. 2 is a view showing a deposition device and a deposition method according to a comparative example,

Referring to FIG. 2, the deposition device 1000c according to a comparative example includes only the fourth deposition source 210c and the fifth deposition source 220c disposed on a base, and includes three angle limitation plates 310c, 320c, and 330c.

The fourth deposition source 210c and the fifth deposition source 220c are sequentially arranged in approximately the first direction DR1 in FIG. 2. Each of the fourth deposition source 210c and the fifth deposition source 220c may include spray holes 211c and 221c through which the vaporized deposition material may be sprayed.

Each of the fourth deposition source 210c and the fifth deposition source 220c may be a linear deposition source that may be extended lengthwise in the third direction DR3 in FIG. 2 to deposit the deposition material while scanning the substrate 110 in the first direction DR1.

The fourth deposition source 210c and the fifth deposition source 220c may move in the first direction DR1 and deposit the deposition material on the substrate 110 to form a film 120c.

The deposition material of the fourth deposition source 210c may include the dopant material as the deposition material, and the fifth deposition source 220c may include the host material as the deposition material. In other examples, the deposition material of the fourth deposition source 210c may include the host material as the deposition material, and the fifth deposition source 220c may include the dopant material as the deposition material.

Three angle limitation plates 310c, 320c, and 330c include the fifth angle limitation plate 310c disposed outside the fourth deposition source 210c, the sixth angle limitation plate 320c disposed between the fourth deposition source 210c and the fifth deposition source 220c, and the seventh angle limitation plate 330c disposed outside the fifth deposition source.

The fifth angle limitation plate 310c may limit the incident angle so that the left edge of the profile 21c of the deposition material injected from the fourth deposition source 210c is incident on the substrate 110 at a seventh incident angle C10, and the sixth angle limitation plate 320c may limit the incident angle so that the right edge of the profile 21c of the deposition material injected from the fourth deposition source 210c is incident on the substrate 110 at an eighth incident angle C11.

The sixth angle limitation plate 320c may limit the incident angle so that the left edge of the profile of the deposition material 22c injected from the fifth deposition source 220c is incident on the substrate 110 at a ninth incident angle C20, and the seventh angle limitation plate 330c may limit the incident angle so that the right edge of the profile of the deposition material 22c injected from the fifth deposition source 220c is incident on the substrate 110 at a tenth incident angle C21.

The seventh incident angle C10 and the tenth incident angle C21 are greater than the eighth incident angle C11 and the ninth incident angle C20. The seventh incident angle C10 may be equal to the tenth incident angle C21, and the eighth incident angle C11 may be equal to the ninth incident angle C20.

The region in which the deposition material from the fourth deposition source 210c is deposited on the substrate 110 and the region in which the deposition material from the fifth deposition source 220c is deposited on the substrate 110 may overlap each other.

The deposition device 1000c according to a comparative example may deposit with one scan in the first direction DR1 relative to the substrate 110, or may deposit with one or more reciprocations (e.g., moving back and forth in the first direction DR1).

FIG. 3 is a graph showing a ratio of a dopant and a host depending on a thickness of a layer deposited according to a deposition method of the comparative example.

FIG. 3 shows the ratio of the dopant and the host according to the thickness of the layer 120c which was deposited by the comparative example deposition device 1000c shown in FIG. 2 moving back-and-forth two times over the substrate 110. The fourth deposition source 210c may include a dopant material, and the fifth deposition source 220c may include the host material.

Referring to FIG. 3, the ratio of the host and the dopant in the thickness direction of the layer 120c deposited by the deposition device 1000c according to the comparative example shows a large deviation of the dopant ratio compared to the change of the host ratio. The dopant ratio in FIG. 3 varies from a maximum of about 15.82% to a minimum of about 5.05%. Accordingly, the deviation of the dopant ratio may be as high as 10.77%. In the comparative example, the doping structure is not uniformly formed in the film thickness direction, and when an emission layer is formed, performance of the light-emitting element including the emission layer may deteriorate, and the lifespan may deteriorate quickly.

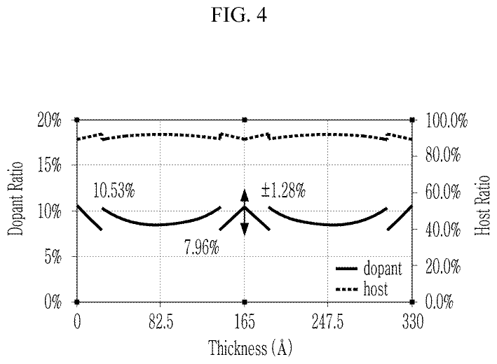

The emission layer deposited using the deposition method according to an embodiment and its effects may be compared to the comparative example in FIGS. 4 to 8.

FIG. 4 is a graph showing a ratio of a dopant and a host depending on the thickness of the layer deposited using a deposition method according to an embodiment,

FIG. 4 shows the ratio of the dopant and the host according to the thickness of the emission layer 120 deposited using the deposition device 1000 according to the embodiment of FIG. 1 moving back-and-forth two times over the substrate 110.

Referring to FIG. 4, the ratio of the host and the dopant of the emission layer 120 in the thickness direction may show that the deviation of the dopant ratio compared to the change in the host ratio may be smaller than that of the comparative example. The dopant ratio in FIG. 4 varies from a maximum of about 10.53% to a minimum of about 7.96%. Accordingly, the deviation of the dopant ratio is about 2.57%, which is approximately ±1.28% based on the median value. Compared to the comparative example described above, the doping uniformity in the thickness direction of the emission layer may be improved using the deposition method according to the embodiment. Accordingly, performance of the light-emitting element that includes the emission layer formed by the deposition process according to an embodiment may be improved, and the lifespan may also be improved. This is described in detail below.

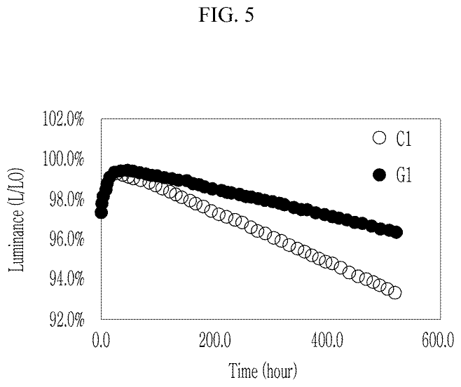

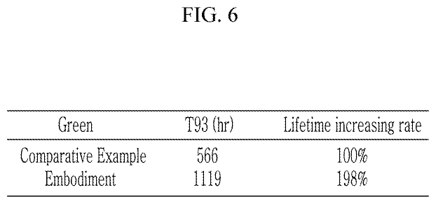

FIG. 5 is a graph comparing the luminance change over time for a pixel of a color formed using a deposition device according to an embodiment and a pixel formed using a deposition device according to a comparative example. The table in FIG. 6 shows the lifetime increasing rate of a light-emitting element of a color formed using a deposition device according to an embodiment compared to a light-emitting element formed using a deposition device according to a comparative example.

The curve G1 in FIG. 5 shows the change rate of the ratio of luminance L to the initial luminance LO of a green pixel including an emission layer deposited by the deposition device 1000 according to an embodiment. The curve C1 in FIG. 5 shows the change rate of the ratio of luminance L to the initial luminance LO of a green pixel including an emission layer deposited by the deposition device 1000c according to the comparative example shown in FIG. 2.

Referring to FIG. 5, the luminance change over time of the green pixel including the emission layer deposited by the deposition device 1000 according to an embodiment is slower and smaller than the luminance change of the green pixel including the emission layer deposited by the deposition device 1000c according to the comparative example.

Referring to FIG. 6, the time T93 taken for the luminance to drop to 93% for the green light-emitting element that includes an emission layer deposited with the deposition device 1000c according to the comparative example is about 566 hours. The time T93 taken for the luminance to drop to 93% for the green light-emitting element including an emission layer deposited with the deposition device 1000 according to an embodiment is longer, at about 1119 hours. Accordingly, the lifetime increasing rate of the green light-emitting element including an emission layer deposited by the deposition device 1000 according to an embodiment is about 198% compared to the comparative example deposition device 1000c.

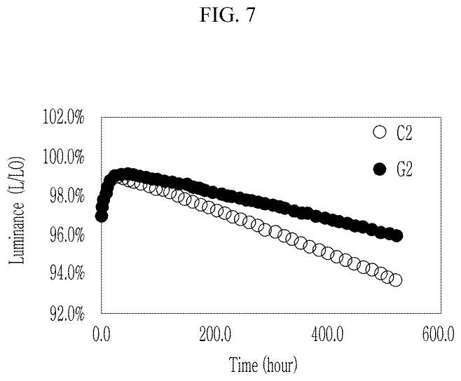

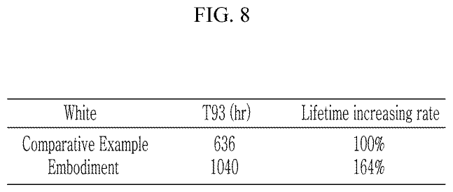

FIG. 7 is a graph comparing the luminance change over time for pixels of all colors (e.g., pixels that produce a white light) formed using a deposition device according to an embodiment and the luminance change for pixels formed using a deposition device according to a comparative example. The table in FIG. 8 is a table shows the lifetime increasing rate of light-emitting elements of all colors (e.g., light-emitting elements that produce a white light) formed using a deposition device according to an embodiment compared to light emitting elements of all colors formed using a deposition device according to a comparative example.

The curve G2 in FIG. 7 shows the change rate of the ratio of luminance L to the initial luminance LO for pixels of all colors, including the green pixel (e.g., pixels that produce a white light), that include emission layers that were deposited by the deposition device 1000 according to an embodiment. The curve C2 in FIG. 7 shows the change rate of the ratio of luminance L to the initial luminance LO for pixels of all colors, including the green pixel, that include emission layers that were deposited by the deposition device 1000c according to the comparative example as shown in FIG. 2.

Referring to FIG. 7, the luminance change for pixels that include emission layers that were deposited by the deposition device 1000 according to an embodiment is slower and smaller than the luminance change for pixels that include emission layers that were deposited by the deposition device 1000c according to comparative example.

Referring to FIG. 8, the time T93 taken for the luminance to drop to 93% for light-emitting elements of all colors, including the green light-emitting element (e.g., that produce a white light), that include emission layers that were deposited with the deposition device 1000c according to the comparative example is about 636 hours. The time T93 taken for the luminance to drop to 93% for light-emitting elements of all colors, including the green light emitting element (e.g., that produce a white light), that include emission layers that were deposited with the deposition device 1000 according to an embodiment is longer at about 1040 hours. Accordingly, the lifetime increasing rate of the light-emitting elements of all colors, including the green light-emitting element, that include emission layers that were deposited by the deposition device 1000 according to an embodiment is about 164% compared to the comparative example deposition device 1000c.

In the deposition process using the deposition device 1000 according to an embodiment, compared with the comparative example, the first deposition source 210 and the third deposition source 230 deposit the same dopant materials from the sides of the host material from the second deposition source 220. In order to form a layer with the same thickness as the emission layer formed using the comparative example deposition device 1000c, the injection amount of the deposition material from each of the first deposition source 210 and the third deposition source 220 may be reduced by half. Therefore, thermal degradation of the dopant deposition material may be reduced.

In the deposition process using the deposition device 1000 according to an embodiment, the third incident angle A20 (refer to FIG. 1) and the fourth incident angle A21 (refer to FIG. 1), which are the deposition angles of the second deposition source 220 disposed in the middle between the first deposition source 210 and the third deposition source 230, may be lower than the deposition angles of the comparative example (the seventh incident angle C10 and eighth incident angle C11 in FIG. 2). It may be possible to increase the use efficiency of the deposition material. Therefore, thermal degradation of the host deposition material may be reduced.

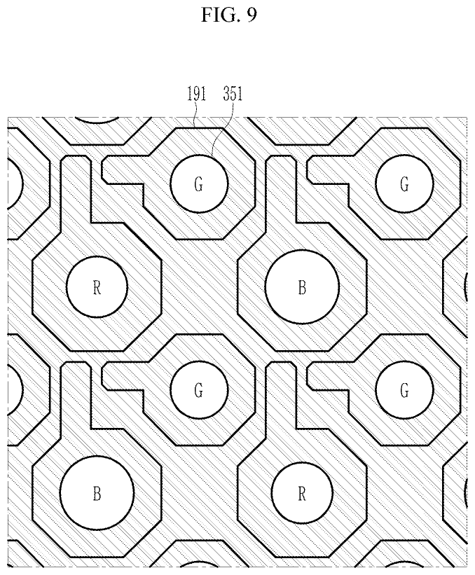

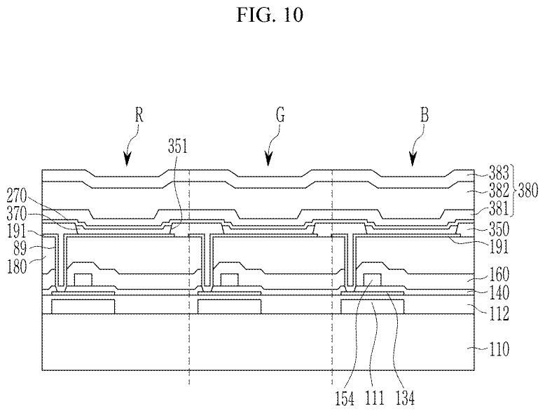

An example of a display device including the emission layer deposited using the deposition device 1000 according to an embodiment is described with reference to FIG. 9 and FIG. 10.

FIG. 9 is a schematic plan view of a display device according to an embodiment, and FIG. 10 is a schematic cross-sectional view of a display device according to an embodiment.

A display device according to an embodiment includes pixels, which are basic units for displaying an image. The pixels include color pixels capable of emitting light of different colors. FIG. 9 shows an example in which the pixels include a red pixel R, a green pixel G. and a blue pixel B.

The red pixel R and the blue pixel B may be alternately arranged in the horizontal direction, the blue pixel B and the green pixel G may be alternately arranged in a diagonal direction, and the red pixel R and the green pixel G may be alternately arranged in another diagonal direction. However, the arrangement of the pixels is not limited thereto.

Referring to FIG. 10, the display device according to an embodiment may include a substrate 110 on which pixels R, G, and B are positioned. The substrate 110 may include an insulating material such as glass or plastic, and may be flexible.

A first conductive layer including a conductive pattern 111 and signal lines (not illustrated) and voltage lines (not illustrated) may be disposed on the substrate 110. The first conductive layer may include conductive metals or conductive semiconductor materials having equivalent characteristics.

A buffer layer 112 that is an insulating layer may be disposed on the first conductive layer, and active patterns 134 may be disposed on the buffer layer 112. The active patterns 134 may include a semiconductor material such as amorphous silicon, polysilicon, or an oxide semiconductor such as IGZO.

A first insulating layer 140 may be disposed on the active patterns 134, and a second conductive layer including a gate electrodes 154 may be disposed on the first insulating layer 140. The active patterns 134 and the gate electrodes 154 together may form a thin film transistor.

At least one of the first conductive layer and the second conductive layer may include at least one of a metal such as copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), and alloys thereof.

A second insulating layer 160 may be disposed on the second conductive layer, and a third insulating layer 180 may be disposed on the second insulating layer 160.

At least one of the buffer layer 112, the second insulating layer 160, and the third insulating layer 180 may include an inorganic insulating material such as a silicon nitride (SiNx), a silicon oxide (SiOx), and a silicon oxynitride (SiOxNy) and/or an organic insulating material. The second insulating layer 160 may be omitted.

A third conductive layer including pixel electrodes 191 may be disposed on the third insulating layer 180. The pixel electrode 191 may be electrically connected to the conductive region of the active pattern 134 through an opening 89 of the first insulating layer 140, the second insulating layer 160, and the third insulating layer 180.

The third conductive layer may include a semi-transparent conductive material or a reflective conductive material.

A fourth insulating layer 350 may be disposed on the third conductive layer. The fourth insulating layer 350 may have an opening 351 disposed on the pixel electrode 191 of each pixel R, G, and B, respectively.

The fourth insulating layer 350 may include an organic insulating material such as a photoresist, a polyacryl-based resin, a polyimide-based resin, an acryl-based resin, or a silicone compound.

The emission layers 370 may be disposed on each pixel electrode 191. The emission layers 370 may include a portion disposed within the opening 351 of the fourth insulating layer 350. The emission layers 370 may be deposited using the deposition device 1000 of an embodiment described above in FIG. 1.

The emission layers 370 may include an organic light emitting material or an inorganic light emitting material, and may include a host material and a dopant material.

A common electrode 270 may be disposed on the emission layers 370. The common electrode 270 may be continuously formed over pixels R, G, and B. The common electrode 270 may include a conductive transparent material.

Each pixel electrode 191, emission layer 370, and common electrode 270 together form a light emitting diode (LED), which is a light-emitting element, and the pixel electrode 191 or the common electrode 270 may serve as a cathode and the other may serve as an anode.

Referring to FIG. 9 and FIG. 10, a region in which an opening 351 of the fourth insulating layer 350 is disposed on the pixel electrode 191 may be the light emitting region of each of the pixels R, G, and B.

An encapsulation layer 380 including multiple insulating layers 381, 382, and 383 may be disposed on the common electrode 270. The insulating layer 381 and the insulating layer 382 may include an inorganic insulating material, and the insulating layer 382 disposed between the insulating layer 381 and the insulating layer 382 may include an organic insulating material.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A deposition device comprising:
a first deposition source, a second deposition source, and a third deposition source arranged sequentially in a first direction;
a first angle limitation plate disposed outside of the first deposition source;
a second angle limitation plate disposed between the first deposition source and the second deposition source;
a third angle limitation plate disposed between the second deposition source and the third deposition source; and
a fourth angle limitation plate disposed outside of the third deposition source, wherein
a deposition material from the first deposition source and a deposition material from the third deposition source include a same dopant material, and
a deposition material from the second deposition source includes a host material.

2. The deposition device of claim 1, wherein
the host material from the second deposition source includes a host material of a green emission layer, and
the dopant material from the first deposition source and the dopant material from the third deposition source include a dopant material of the green emission layer.

3. The deposition device of claim 1, wherein the first deposition source, the second deposition source, and the third deposition source move in the first direction and spray the deposition material.

4. The deposition device of claim 3, wherein the first deposition source, the second deposition source, and the third deposition source extend in a second direction substantially perpendicular to the first direction.

5. The deposition device of claim 4, wherein
each of the first deposition source, the second deposition source, and the third deposition source includes a spray hole, and
the spray hole includes spray nozzles arranged in the second direction, or includes a linear nozzle that extends in the second direction.

6. The deposition device of claim 1, wherein
an incident angle from the first deposition source to a substrate of the deposition material limited by the first angle limitation plate is a first incident angle,
an incident angle from the first deposition source to the substrate of the deposition material limited by the second angle limitation plate is a second incident angle,
an incident angle from the second deposition source to the substrate of the deposition material limited by the second angle limitation plate is a third incident angle,
an incident angle from the second deposition source to the substrate of the deposition material limited by the third angle limitation plate is a fourth incident angle,
an incident angle from the third deposition source to the substrate of the deposition material limited by the third angle limitation plate is a fifth incident angle,
an incident angle from the third deposition source to the substrate of the deposition material limited by the fourth angle limitation plate is a sixth incident angle, and
each of the first incident angle and the sixth incident angle is larger than either of the third incident angle or the fourth incident angle.

7. The deposition device of claim 6, wherein each of the third incident angle and the fourth incident angle is larger than either of the second incident angle or the fifth incident angle.

8. The deposition device of claim 7, wherein each of a height of the first angle limitation plate and a height of the fourth angle limitation plate is higher than either of a height of the second angle limitation plate or a height of the third angle limitation plate.

9. The deposition device of claim 7, wherein
the first incident angle and the sixth incident angle are substantially equal to each other,
the third incident angle and the fourth incident angle are substantially equal to each other, and
the second incident angle and the fifth incident angle are substantially equal to each other.

10. The deposition device of claim 9, wherein
a height of the first angle limitation plate and a height of the fourth angle limitation plate are substantially equal to each other, and
a height of the second angle limitation plate and a height of the third angle limitation plate are substantially equal to each other.

11. The deposition device of claim 9, wherein
the first incident angle and the sixth incident angle are in a range of about 72 degrees to about 82 degrees,
the third incident angle and fourth incident angle are in a range of about 55 degrees to about 65 degrees, and
the second incident angle and fifth incident angle are in a range of about 50 degrees to about 60 degrees.

12. The deposition device of claim 1, wherein
a region where the dopant material from the first deposition source is deposited on a substrate, and a region where the dopant material from the third deposition source is deposited on the substrate partially overlap in a plan view,
a region where the host material from the second deposition source is deposited on the substrate overlaps substantially all of the region where the dopant material from the first deposition source is deposited on the substrate, in a plan view, and
the region where the host material from the second deposition source is deposited on the substrate overlaps substantially all of the region where the dopant material from the third deposition source is deposited on the substrate, in a plan view.

13. A deposition device comprising:
a first deposition source, a second deposition source, and a third deposition source arranged sequentially in a direction, wherein
a deposition material from the first deposition source and a deposition material from the third deposition source include a same dopant material,
a deposition material from the second deposition source includes a host material,
a region where the dopant material from the first deposition source is deposited on a substrate, and a region where the dopant material from the third deposition source is deposited on the substrate partially overlap, in a plan view,
a region where the host material from the second deposition source is deposited on the substrate overlaps substantially all of the region where the dopant material from the first deposition source is deposited on the substrate, in a plan view, and
the region where the host material from the second deposition source is deposited on the substrate overlaps substantially all of the region where the dopant material from the third deposition source is deposited on the substrate, in a plan view.

14. The deposition device of claim 13, wherein
the host material from the second deposition source includes a host material of a green emission layer, and
the dopant material from the first deposition source and the dopant material from the third deposition source include a dopant material of the green emission layer.

15. The deposition device of claim 13, wherein the first deposition source, the second deposition source, and the third deposition source move in the direction and spray the deposition material.

16. The deposition device of claim 15, further comprising:
a first angle limitation plate disposed outside of the first deposition source;
a second angle limitation plate disposed between the first deposition source and the second deposition source;
a third angle limitation plate disposed between the second deposition source and the third deposition source; and
a fourth angle limitation plate disposed outside of the third deposition source.

17. The deposition device of claim 16, wherein
each of a height of the first angle limitation plate and a height of the fourth angle limitation plate is higher than either of a height of the second angle limitation plate or a height of the third angle limitation plate,
the height of the first angle limitation plate and the height of the fourth angle limitation plate are substantially equal to each other, and
the height of the second angle limitation plate and the height of the third angle limitation plate are substantially equal to each other.

18. A deposition method comprising:
moving a first deposition source, a second deposition source, and a third deposition source in a direction with respect to a substrate;
depositing a dopant material from the first deposition source and from the third deposition source on the substrate; and
depositing a host material from the second deposition source on the substrate, wherein
a deposition device includes the first deposition source, the second deposition source, the third deposition source, and angle limitation plates
the first deposition source, the second deposition source, and the third deposition source are sequentially arranged in the direction.

19. The deposition method of claim 18, wherein
the host material from the second deposition source includes a host material of a green emission layer, and
the dopant material from the first deposition source and from the third deposition source includes a dopant material of the green emission layer.

20. The deposition method of claim 18, wherein
the angle limitation plates include a first angle limitation plate, a second angle limitation plate, a third angle limitation plate, and a fourth angle limitation plate,
the first angle limitation plate, the second angle limitation plate, the third angle limitation plate, and the fourth angle limitation plates are arranged sequentially in the direction,
an incident angle from the first deposition source to the substrate of the deposition material limited by the first angle limitation plate is a first incident angle,
an incident angle from the first deposition source to the substrate of the deposition material limited by the second angle limitation plate is a second incident angle,
an incident angle from the second deposition source to the substrate of the deposition material limited by the second angle limitation plate is a third incident angle,
an incident angle from the second deposition source to the substrate of the deposition material limited by the third angle limitation plate is a fourth incident angle,
an incident angle from the third deposition source to the substrate of the deposition material limited by the third angle limitation plate is a fifth incident angle, and
an incident angle from the third deposition source to the substrate of the deposition material limited by the fourth angle limitation plate is a sixth incident angle,
the first incident angle and the sixth incident angle are in a range of about 72 degrees to about 82 degrees,
the third incident angle and the fourth incident angle are in a range of about 55 degrees to about 65 degrees, and
the second incident angle and the fifth incident angle are in a range of about 50 degrees to about 60 degrees.
